(19) United States
(12) Patent Application Publication
(10) Pub. No.: US 2026/0058912 A1
(43) Pub. Date: Feb. 26, 2026

(54) DATA REARRANGEMENT SYSTEM AND METHOD

(71) Applicant: Nuvoton Technology Corporation, Hsinchu Science Park (TW)

(72) Inventor: Yeh-Hsing Hou, Kaohsiung City (TW)

(21) Appl. No.: 19/014,699

(22) Filed: Jan. 9, 2025

(30) Foreign Application Priority Data
Aug. 23, 2024 (TW) 113131799

(51) Int. Cl. H04L 47/2441; H03M 7/28; H04L 41/14

(52) U.S. Cl. CPC H04L 47/2441; H03M 7/28; H04L 41/145

(57) ABSTRACT

A data rearrangement system is provided. The system includes a data-encoding device and a data-decoding device. The data-encoding device is configured to receive one or more data streams from one or more end devices. The data-encoding device is configured to generate a data-encoding pattern based on quality of service (QoS) information, scheduling policy, and transmission information of the data streams using a neural network model. The data-encoding device is configured to encode the data streams to generate an encoded data stream with an encoder, according to the data-encoding pattern. The data-encoding device is configured to transmit the data-encoding pattern and the encoded data stream to the data-decoding device. The data-decoding device is configured to restore the data stream according to the data-encoding pattern and the encoded data stream.

### CROSS REFERENCE TO RELATED APPLICATIONS

This application claims priority of Taiwan Application No. 113131799, filed on Aug. 23, 2024, the entirety of which is incorporated by reference herein.

### BACKGROUND OF THE INVENTION

### Field of the Invention

The present invention relates to data transmission technology, and, in particular, to a system and method for data rearrangement.

### Description of the Related Art

Currently, the order of data processing (e.g., transmission) is mainly determined by a scheduler, e.g., a packet scheduler or an input/output (I/O) scheduler. The scheduler is a component in a computer system that is responsible for managing and scheduling resources. It can determine the order in which data is processed (e.g., transmitted) based on preset rules. This improves the computing efficiency and reliability of the computer system.

A packet scheduler, for example, is the core component in the network device responsible for managing and controlling the order of network packet transmission. It mainly classifies and sorts packets according to the user's preset scheduling policy or algorithm to ensure fairness and quality of service (QoS) between different data streams. Common scheduling policies include first-in, first-out (FIFO), shortest job first (SJF), fair queuing (FQ), priority (PRIO), etc.

However, under the above-mentioned scheduling policies, when the transmission capabilities of end devices in the network system are unevenly distributed, a certain end device initiating a large number of transmissions may use up a large amount of resources (e.g., bandwidth and memory resources). As a result of this, the transmission needs of others cannot be met immediately, and starvation may occur. For example, when an end device continuously transmits a large number of packets using User Datagram Protocol (UDP), even if UDP allows packet loss, the above scheduling policies provide no way to prune the traffic of the end device. This makes it so that resources (e.g., bandwidth) are unable to be released to other end devices.

Accordingly, a data rearrangement system and method that can solve the above uneven distribution problem of transmission resources is needed.

### BRIEF SUMMARY OF THE INVENTION

An embodiment of the present invention provides a data rearrangement system. The data rearrangement system comprises a data-decoding device and a data-encoding device. The data-encoding device is configured to receive one or more data streams. The data-encoding device is configured to generate a data-encoding pattern through a neural network model based on quality of service (QoS) information, a scheduling policy and transmission information of the data streams. The data-encoding device is configured to generate an encoded data stream with an encoder by encoding the data streams according to the data-encoding pattern. The data-encoding device is configured to transmit the data-encoding pattern and the encoded data stream to the data-decoding device. The data-decoding device restores the encoded data stream to the data streams according to the data-encoding pattern.

An embodiment of the present invention provides a data rearrangement method. The data rearrangement method is executed by a computer system comprising a data-encoding device and a data-decoding device. The data rearrangement method comprises the following actions. The data-encoding device receives one or more data streams. The data-encoding device generates a data-encoding pattern using a neural network model based on quality of service (QoS) information, scheduling policy, and transmission information of the data streams. The data-encoding device generates an encoded data stream through an encoder by encoding the data streams according to the data-encoding pattern. The data-encoding device transmits the data-encoding pattern and the data stream to the data-decoding device. The data rearrangement method also comprises using the data-decoding device to restore the encoded data stream to the data streams according to the data-encoding pattern.

Various embodiments of the system and method provided by the present disclosure can be applied to various scenarios that require data transmission, such as but not limited to various communication networks or data storage. By rearranging the order of transmission data between different streams, transmission resources can be better allocated and utilized. This improves the efficiency and reliability of data transmission. Furthermore, compared with rule-based scheduling policies, the system and method provided in this disclosure can flexibly rearrange the transmission data between different streams based on current transmission resources (e.g., QoS information), characteristics of the data streams (e.g., transmission information) and scheduling policies. This optimizes the underlying scheduling policy, and thus improves the efficiency and reliability of data transmission.

### BRIEF DESCRIPTION OF THE DRAWINGS

The present invention can be more fully understood by reading the subsequent detailed description and examples with references made to the accompanying drawings. In addition, it should be understood that in the flowchart of the present disclosure, the execution order of each block may be changed, and/or some blocks may be changed, deleted, or combined.

FIG. 1 is a system architecture diagram of a data rearrangement system according to an embodiment of the present invention.

FIG. 2 is a flow chart of a data rearrangement method according to an embodiment of the present invention.

FIG. 3A is a block diagram of a data-encoding device that implements some of the steps shown in FIG. 2.

FIG. 3B is a block diagram of a data-decoding device that implements some of the steps shown in FIG. 2.

FIG. 4 is a block diagram of a data-encoding device applying a binary-array data-encoding pattern.

FIG. 5 is a flow chart for updating a data-encoding pattern according to an embodiment of the present invention.

FIG. 6A is a schematic diagram of a padding operation according to an embodiment of the present invention.

FIG. 6B is a schematic diagram of a pruning operation according to an embodiment of the present invention.

FIG. 6C is a schematic diagram of a balancing operation according to an embodiment of the present invention.

### DETAILED DESCRIPTION OF THE INVENTION

The following description is made for the purpose of illustrating the general principles of the invention and should not be taken in a limiting sense. The scope of the invention is best determined by reference to the appended claims.

In each of the below embodiments, the same or similar elements or components will be represented by the same reference numerals.

The serial numbers in this description and the scope of the patent application, such as “first”, “second”, etc., are only for convenience of explanation, and there is no sequential relationship between them.

The description of the embodiments of the device or system in this disclosure also applies to the embodiments of the method, and vice versa.

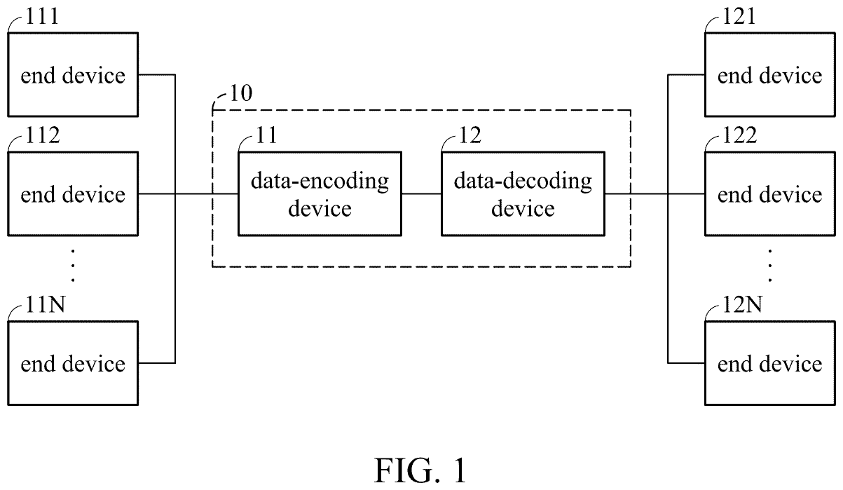

FIG. 1 is a system architecture diagram of a data rearrangement system 10 according to an embodiment of the present invention. As shown in FIG. 1, the data rearrangement system 10 may include a data-encoding device 11 and a data-decoding device 12, which may communicate with each other. It should be noted that although in the example of FIG. 1 the data-encoding device 11 and the data-decoding device 12 of the data rearrangement system 10 communicate with multiple end devices 111-11N and 121-12N respectively, the present disclosure does not limit the number of the end devices. In some embodiments, each of the data-encoding device 11 and the data-decoding device 12 can only communicate with a single end device.

The end devices 111-11N and 121-12N can be any computer system or processing device with computing capabilities, e.g., a personal computer (e.g., desktop or laptop), a server, a mobile device (e.g., tablet or smart phone) or bridge IC (BIC). However, this disclosure is not limited thereto.

The above computer system and the BIC may each include a processing unit and a memory unit. The processing unit of the computer system may include any one or more general-purpose or special-purpose processors and combinations thereof for executing instructions, e.g., a central processing unit (CPU) and/or a graphics processing unit (GPU). The memory unit of the computer system can include a hard disk (HDD), a solid state drive (SSD), an optical disk, and any kind of device with non-volatile memory (e.g., read-only memory, electronically erasable memory (EEPROM), flash memory, non-volatile random access memory (NVRAM)). It may also include volatile memories, e.g., dynamic random access memory (DRAM) and/or static random access memory (SRAM). However, the disclosure is not limited thereto. The processing unit of the BIC may include a microcontroller, a microprocessor or various embedded controllers. This disclosure is not limited thereto. The memory unit of the BIC may include cache memory, register, static random access memory and/or other forms of memory. This disclosure is not limited thereto.

The data-encoding device 11 and the data-decoding device 12 can be any computer system with computing capabilities, e.g., personal computer (e.g., desktop or laptop), a server, or a baseboard management controller (BMC), router, or mobile devices such as tablets or smartphones. This disclosure is not limited thereto. Like the aforementioned end devices 111-11N and 121-12N, the data-encoding device 11 and the data-decoding device 12 may also include a processing unit and a memory unit.

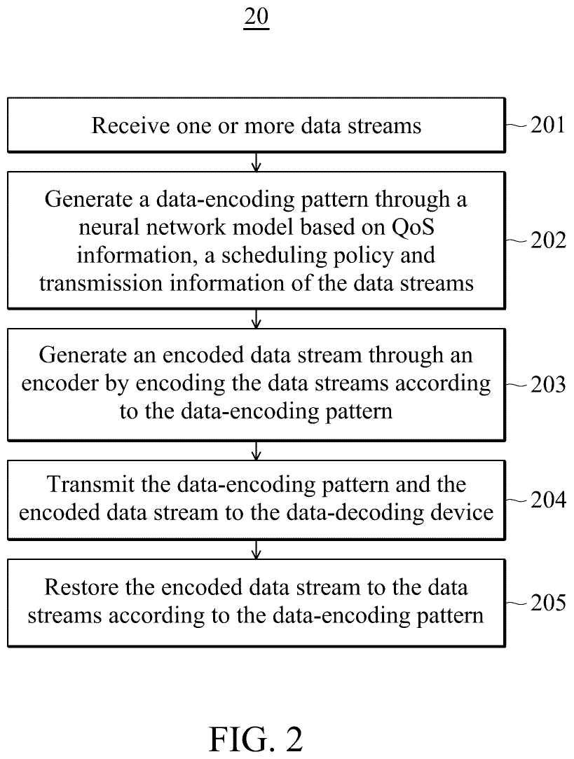

In various embodiments, the data rearrangement system 10 implements a data rearrangement method, which will be described below with reference to FIG. 2.

FIG. 2 is a flow chart of a data rearrangement method 20 according to an embodiment of the present invention. As shown in FIG. 2, the data rearrangement method 20 includes steps 201-205, where steps 201-204 are implemented by the data-encoding device 11, and step 205 is implemented by the data-decoding device 12.

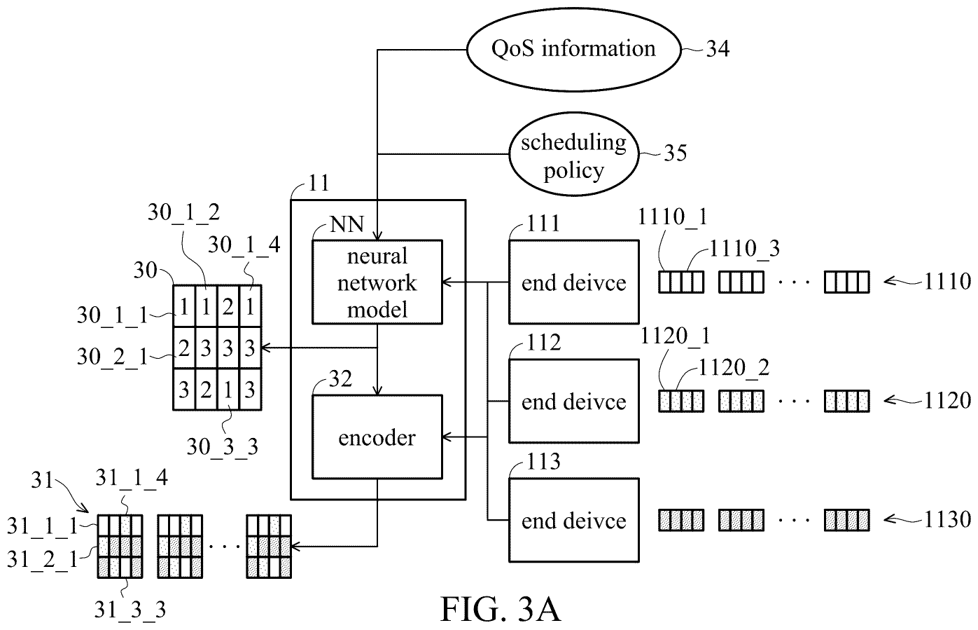

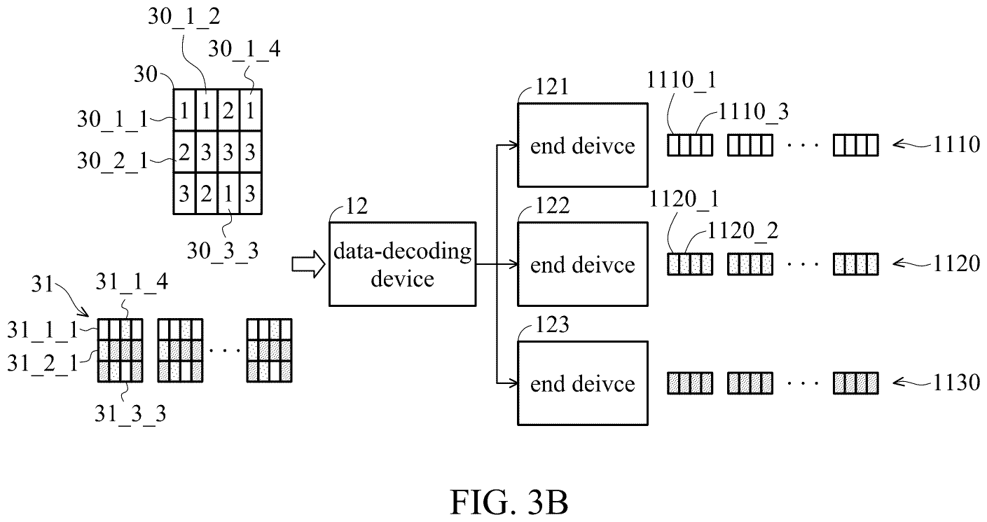

Correspondingly, FIG. 3A is a block diagram of the data-encoding device 11 that implements steps 201-204 shown in FIG. 2 in this embodiment. FIG. 3B is a block diagram of the data-encoding device 12 that implements steps 205 shown in FIG. 2 in this embodiment. The data-encoding device 11 executes the neural network model NN and the encoder 32. Please refer to FIGS. 2, 3A and 3B together with the corresponding descriptions below to understand this embodiment more clearly.

In step 201, the data-encoding device 11 receives the data streams 1110-1130 from the end devices 111-113 respectively.

In step 202, the data-encoding device 11 generates a data-encoding pattern 30 based on QoS information 34, scheduling policy 35 and transmission information of the data streams 1110-1130 through a neural network model NN.

More specifically, the data-encoding device 11 inputs the QoS information 34, the scheduling policy 35 and the transmission information of the data streams 1110-1130 into the trained neural network model NN, and obtains the data-encoding pattern 30 output by the neural network model NN. In an implementation, before inputting the QoS information 34, the scheduling policy 35 and the transmission information of the data streams 1110-1130 into the neural network model NN, the data-encoding device 11 further performs a preprocessing operation to enhance the performance of the neural network model NN. The preprocessing operations may include, e.g., noise reduction, missing data filling, feature scaling (e.g., normalization, standardization, etc.), and one-hot encoding (OHE), etc. This disclosure is not limited thereto.

The QoS information 34 is used for evaluating the transmission performance of the transmission path between the data-encoding device 11 and the data-decoding device 12. The transmission performance may include transmission bandwidth, latency, jitter, packet loss rate or throughput, etc. The disclosure is not limited thereto.

In one embodiment, the data-encoding device 11 can obtain the QoS information 34 from an external device. In another embodiment, the data-encoding device 11 can obtain the QoS information 34 by using a traffic analysis tool or a network management tool, or by calling an application programming interface (API) or function library provided by the operating system. The disclosure does not limit the specific way to obtain the QoS information 34. Taking the Linux operating system as an example, information related to traffic statistics and QoS settings can be obtained by opening and reading the file/proc/net/dev, or using the command line command netstat. Taking the Windows operating system as an example, relevant information about network performance such as throughput and latency can be obtained through the traffic analysis tool iPerf.

The scheduling policy 35 can be set on the underlying hardware (e.g., network interface card) or the operating system of the data-encoding device 11 by the user to determine the order to output packets. For example, it can be first-in, first-out (FIFO), shortest job first (SJF), fair queuing (FQ) and priority (PRIO), etc. This disclosure is not limited thereto.

In one embodiment, the scheduling policy 35 can be obtained by calling an API or a function library provided by the operating system, and/or by using a network management tool. Taking the Linux operating system as an example, by opening and reading the file/proc/net/dev, relevant information about the network/packet scheduling policy can be obtained.

Each of the data streams 1110-1130 may include a plurality of packets. Each of these packets may include a plurality of data blocks. The transmission information of the data streams 1110-1130 may include data size, data type, transmission behavior, etc. The present disclosure is not limited thereto. The transmission information of the data streams 1110-1130 can be obtained by analyzing the header of the packets of the data streams 1110-1130 or traffic statistics. For example, when the application-layer port in the header is 554, it can be seen that the protocol is Real-Time Streaming Protocol (RTSP) and the data type is multimedia data. For another example, in the Linux operating system, the file/proc/net/dev can be opened and read to obtain traffic statistics for the data stream, to evaluate the transmission behavior (e.g., excessive or unstable traffic) of the data stream.

In one embodiment, the data-encoding pattern 30 is a multi-dimensional array, each element of which indicates which of the data streams 1110-1130 a certain data block of the encoded data stream 31 output by the encoder 32 originates from. In one implementation, each element in the data-encoding pattern 30 can record an identification code of the data stream, so that the encoder 32 can encode the data stream accordingly.

In the example of FIG. 3A, the data-encoding pattern 30 is a 3×4 two-dimensional array. Element value 1 represents that the data block at the corresponding arrangement position of the data stream output by the data-encoding device 11 is from the data stream 1110 of end device 111. Element value 2 represents that the data block at the corresponding arrangement position of the data stream output by the data-encoding device 11 is from the data stream 1120 of the end device 112. Element value 3 represents that the data block at the corresponding arrangement position of the data stream output by the data-encoding device 11 is from the data stream 1130 of end device 113. It should be understood that the data-encoding pattern 30 depicted in FIG. 3A is only an example and not a limitation. This disclosure does not limit the specific design of the data-encoding pattern 30, such as dimensions and sizes.

In one embodiment, in the training phase of the neural network model NN, after inferring the data-encoding pattern based on the QoS information, the scheduling policy and the data streams, the data-encoding device 11 may calculate loss for the data-encoding pattern 30 according to the rule of the scheduling policy. Then, the data-encoding device 11 may update the neural network model NN based on the loss. Taking the scheduling policy 35 as SJF as an example, the data-encoding device 11 checks whether, in the data-encoding pattern 30, the identification code of the data stream with lower traffic is arranged before the identification code of the data stream with higher traffic. Then, the loss can be calculated accordingly.

Please refer back to FIG. 2. In step 203, the data-encoding device 11 generates the encoded data stream 31 through the encoder 32 by encoding the data streams 1110-1130 according to the data-encoding pattern 30.

More specifically, as shown in FIG. 3A, the data-encoding device 11 inputs the data-encoding pattern 30 and the data streams 1110-1130 to the encoder 32. Next, the encoder 32 encodes the data streams 1110-1130 according to the data-encoding pattern 30. Then, the encoder 32 outputs the encoded data stream 31. Like the data streams 1110-1130, the encoded data stream 31 may also include a plurality of packets, each of which may include a plurality of data blocks.

In one embodiment, the encoder 32 generates the encoded data stream 31 in a column major manner. As shown in FIG. 3A, in this way, for the arrangement positions 30_1_1, 30_1_2, 30_1_4, 30_2_1 and 30_3_3, the logical order is “30_1_1, 30_2_1, 30_1_2, 30_3_3, 30_1_4”. For the first packet of the encoded data stream 31, the data-stream identification code at the arrangement position 30_1_1 of the data-encoding pattern 30 is 1. Therefore, the encoder 32 obtains the first data block 1110_1 of the first packet of the data stream 1110 according to the order of the data blocks of the data stream 1110, and places it at the arrangement position 31_1_1 corresponding to 30_1_1. The data-stream identification code at the arrangement position 30_3_3 of the data-encoding pattern 30 is 1. Therefore, the encoder 32 obtains the third data block 1110_3 of the first packet of the data stream 1110 according to the order of the data blocks of the data stream 1110, and places it at the arrangement position 31_3_3 corresponding to the arrangement position 30_3_3. The data-stream identification code at the arrangement position 30_2_1 of the data-encoding pattern 30 is 2. Therefore, the encoder 32 obtains the first data block 1120_1 of the first packet of the data stream 1120 according to the order of the data blocks of the data stream 1110, and places it at the arrangement position 31_2_1 corresponding to the arrangement position 30_2_1. The encoder 32 works similarly for other arrangement positions in the encoded data stream 31.

In one embodiment, the encoder 32 generates the encoded data stream 31 in a row-major manner. As shown in FIG. 3A, in this way, for the arrangement positions 30_1_1, 30_1_2, 30_1_4, 30_2_1 and 30_3_3, the logical order is “30_1_1, 30_2_1, 30_1_2, 30_3_3, 30_1_4”. For the first packet of the encoded data stream 31, the data-stream identification code at the arrangement position 30_1_1 of the data-encoding pattern 30 is 1. Therefore, the encoder 32 places the first data block 1110_1 of the first packet of the data stream 1110 at the arrangement position 31_1_1. The data-stream identification code at the arrangement position 30_2_1 of the data-encoding pattern 30 is 2. Therefore, the encoder 32 places the second data block 1120_2 of the first packet of the data stream 1120 at the arrangement position 31_2_1. The encoder 32 works similarly for other arrangement positions in the encoded data stream 31.

In another embodiment, the data-encoding pattern 30 is a binary multi-dimensional array. Each element of the data-encoding pattern 30 stores a binary value to indicate the data-encoding device 11 the order to output data of the data streams. For example, an element value of 0 can represent data with a higher priority, an element value of 1 can represent data with a lower priority, and vice versa.

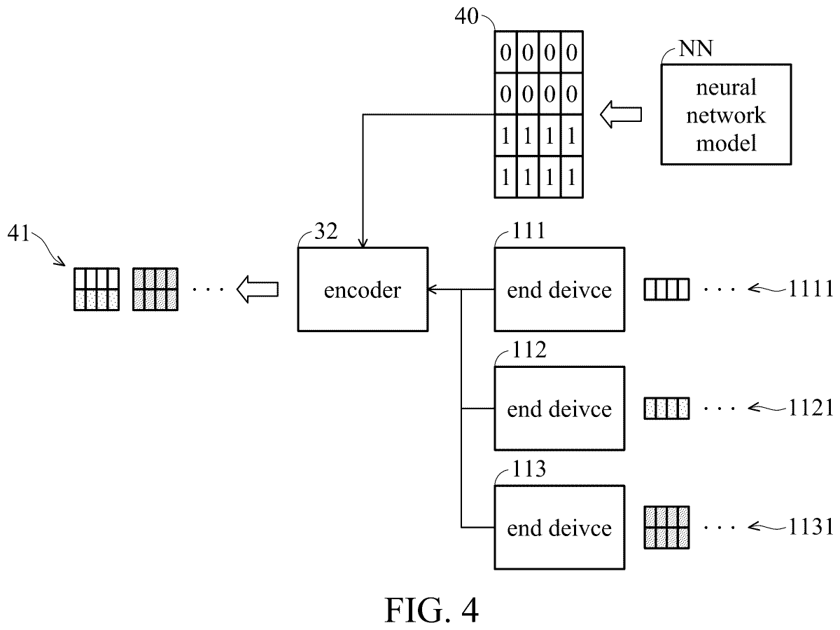

FIG. 4 is a block diagram of a data-encoding device using a binary-array data-encoding pattern. In the example in FIG. 4, the neural network model NN generates a binary data-encoding pattern 40 with a size of 4×4, in which the element value 0 represents to output first and the element value 1 represents to output later. In another embodiment, the element value 1 represents to output first, and the element value 0 represents to output later.

In the example of FIG. 4, the encoder 32 receives the data streams 1111-1131 and the data-encoding pattern 40, and performs binary operations (e.g., NAND) on the data streams 1111-1131 to determine the first data to output. The remaining data is output later. Here, the element value 0 represents to output first, and the element value 1 represents to output later. Therefore, the encoder 32 first outputs the data blocks of the data streams 1111 and 1121, and then outputs the data blocks of the data stream 1131.

The data-encoding pattern 40 in FIG. 4 stores binary values. Compared with the data-encoding pattern 30 in FIG. 3A that stores the data-stream identification code, the data-encoding pattern 40 saves more memory space. In addition, using binary operations helps to further improve the operation speed of the encoder 32.

Please refer back to FIG. 2. In step 204, the data-encoding device 11 transmits the data-encoding pattern 30 and the encoded data stream 31 to the data-decoding device 12. The data-encoding device 11 can transmit the data-encoding pattern 30 and the encoded data stream 31 to the data-decoding device 12 through wired or wireless methods, directly or indirectly (e.g., via the Internet). However, the disclosure is not limited thereto.

In step 205, the data-decoding device 12 restores the encoded data stream 31 into data streams 1110-1130 according to the data-encoding pattern 30.

In the example of FIG. 3B, the data-decoding device 12 receives the data-encoding pattern 30 and the encoded data stream 31, and decodes the encoded data stream 31 according to the data-encoding pattern 30, so as to obtain the data streams 1110-1130.

In one embodiment, the encoder 32 refers to the encoding pattern 30 in a row-major manner and generates the encoded data stream 31. Correspondingly, the data-decoding device 12 also refers to the encoding pattern 30 in a row-major manner, and restores the encoded data stream 31 to the data streams 1110-1130 accordingly. As shown in FIG. 3B, taking the first packet of the encoded data stream 31 as an example, the data-stream identification code at the arrangement position 30_1_1 of the data-encoding pattern 30 is 1. Therefore, the data-decoding device 12 applies the data block at the arrangement position 31_1_1 of the encoded data stream 31 as the first data block 1110_1 of the first packet of the data stream 1110. The data-stream identification code at the arrangement position 30_3_3 of the data-encoding pattern 30 is 1. Therefore, the data-decoding device 12 applies the data block at the arrangement position 31_3_3 of the encoded data stream 31 as the third data block 1110_3 of the first packet of the data stream 1110. The data-stream identification code at the arrangement position 30_2_1 of the data-encoding pattern 30 is 2. Therefore, the data-decoding device 12 applies the data block at the arrangement position 31_2_1 of the encoded data stream 31 as the first data block 1120_1 of the first packet of the data stream 1120. The data-decoding device 12 works similarly for other arrangement positions in the encoded data stream 31.

In one embodiment, the encoder 32 refers to the encoding pattern 30 in a column major manner and generates the encoded data stream 31. Correspondingly, the data-decoding device 12 also refers to the encoding pattern 30 in a column major manner, and restores the encoded data stream 31 to the data streams 1110-1130 accordingly. As shown in FIG. 3B, taking the first packet of the encoded data stream 31 as an example, the data-stream identification code at the arrangement position 30_1_1 of the data-encoding pattern 30 is 1. Therefore, the data-decoding device 12 applies the data block at the arrangement position 31_1_1 of the encoded data stream 31 as the first data block 1110_1 of the first packet of the data stream 1110. The data-stream identification code at the arrangement position 30_1_4 of the data-encoding pattern 30 is 1. Therefore, the data-decoding device 12 applies the data block at the arrangement position 31_1_4 of the encoded data stream 31 as the third data block 1110_3 of the first packet of the data stream 1110. The data-stream identification code at the arrangement position 30_2_1 of the data-encoding pattern 30 is 2. Therefore, the data-decoding device 12 applies the data block at the arrangement position 31_2_1 of the encoded data stream 31 as the second data block 1120_2 of the first packet of the data stream 1120. The data-decoding device 12 works similarly for other arrangement positions in the encoded data stream 31.

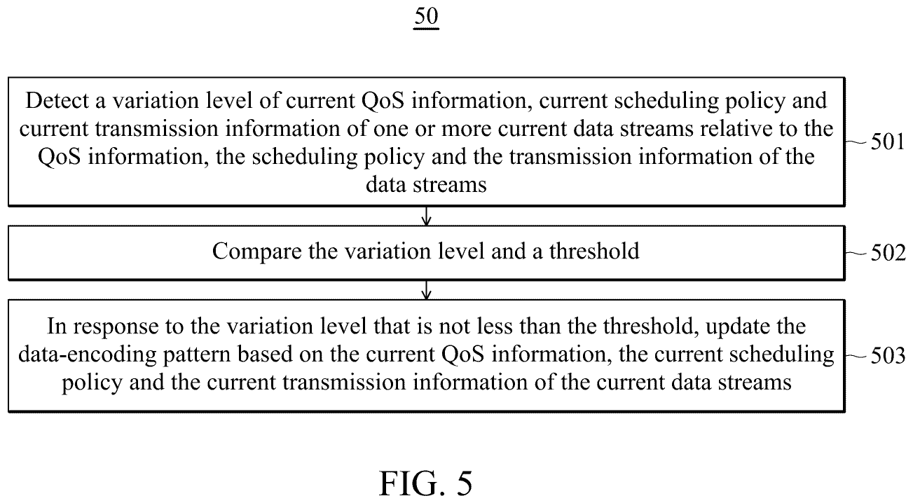

FIG. 5 is a flow chart of a method 50 for updating a data-encoding pattern according to an embodiment of the present invention. The method 50 may be adapted to update the data-encoding patterns 30 and 40.

In step 501, the data-encoding device 11 detects a variation level of the current QoS information, the current scheduling policy, and the current transmission information of the current data streams relative to the original QoS information 34, the original scheduling policy 35, and the original data streams 1110-1130.

In step 502, the data-encoding device 11 compares the variation level with a predefined threshold.

In step 503, in response to the variation level not being less than the threshold, the data-encoding device 11 applies the neural network model NN again to update the data-encoding pattern based on the current QoS information, the current scheduling policy, and the current transmission information of the current data stream. More specifically, the data-encoding device 11 inputs the current QoS information, the current scheduling policy and the current data stream into the neural network model NN, obtains the new data-encoding pattern output by the neural network model NN, and replaces the original data-encoding pattern with the new one. Subsequently, the data-encoding device 11 can encode the received data stream according to the updated data-encoding pattern.

In an embodiment of the present invention, the data-encoding device 11 encodes the data streams 1110-1130 by performing data aggregation on it. This data aggregation involves aggregating data blocks within multiple packets of data streams 1110-1130. More specifically, the data-encoding device 11 performs packet aggregation on the data streams 1110-1130. In other words, the data-encoding device 11 aggregates a plurality of packets of the data streams 1110-1130 into larger packets for output, so as to optimally utilize transmission resources (e.g., bandwidth).

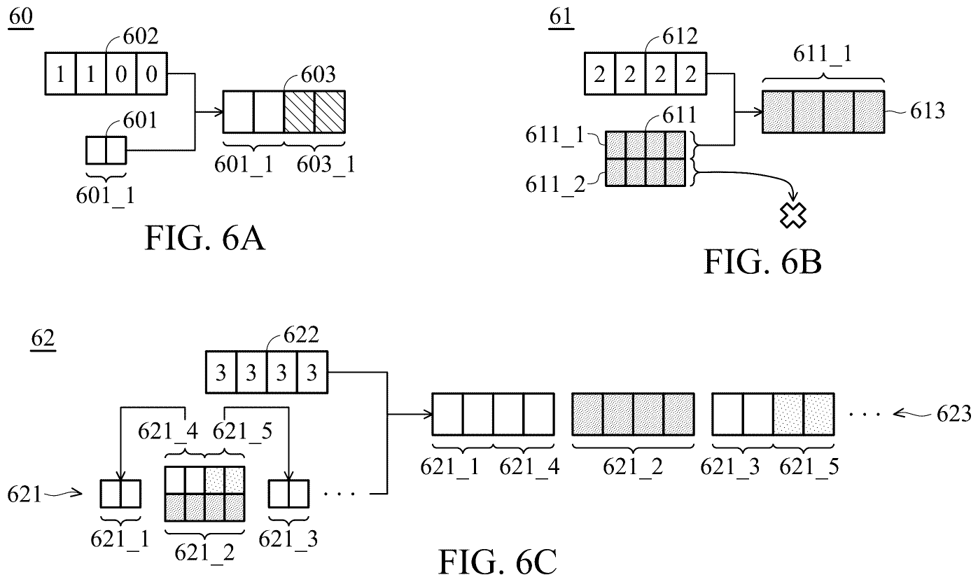

In an embodiment of the present invention, the data-encoding device 11 further performs a padding operation, a pruning operation, a balancing operation or a discarding operation on the data streams 1110-1130, so as to further encode data streams 1110-1130. The above operation will be explained below with reference to FIG. 6A-6C.

FIG. 6A is a schematic diagram of a padding operation 60 according to an embodiment of the present invention. In the example of FIG. 6A, the data-encoding pattern 602 is a 1×4 array, while the data stream 601 is a data block group 601_1 merely composed of two data blocks. The element value 1 in the data-encoding pattern 602 corresponds to the identification code of the data stream 601, and indicates that the data at the corresponding position of the encoded data stream 603 is taken from the data stream 601. The element value 0 in the data-encoding pattern 602 indicates that the data at the corresponding position of the encoded data stream 603 is obtained through the padding operation 60. Therefore, the encoded data stream 603 generated according to the data-encoding pattern 602 includes the data block group 601_1 of the data stream 601 and the padding data block group 603_1 shown with slashes.

FIG. 6B is a schematic diagram of a pruning operation 61 according to an embodiment of the present invention. In the example of FIG. 6B, the data-encoding pattern 612 is a 1×4 array. In the data-encoding pattern 612, the element value 2 corresponds to the identification code of the data stream 611, and indicates that the data at the corresponding position of the encoded data stream 613 is taken from the data stream 611. Since the data block size (traffic) of the data stream 611 exceeds the size of the data-encoding pattern 612, the data stream 611 is pruned after the data-encoding device 11 refers to the data-encoding pattern 612. The data-encoding device 11 keeps only the data block group 611_1 of the data stream 611 as the encoded data stream 613, and ignores the data block group 611_2.

FIG. 6C is a schematic diagram of a balancing operation 62 according to an embodiment of the present invention. In the example of FIG. 6C, the data-encoding pattern 622 is a 1×4 array. In the data-encoding pattern 622, the element value 3 corresponds to the identification code of the data stream 621, and indicates that the data at the corresponding position of the encoded data stream 623 is taken from the data stream 621. The second packet of the data stream 621 has a data block size that exceeds the size of data-encoding pattern 622, and the first and third packets of data stream 621 has a data block size that is smaller than the size of data-encoding pattern 622. Therefore, after referring to the encoding pattern 622, the data-encoding device 11 performs a balancing operation on the data stream 611 to move the excess part (e.g., the data block group 621_4) forward and the other excess part (e.g., the data block group 621_5) backward, so as to form the encoded data stream 623. As shown in FIG. 6C, compared with the uneven size of each packet of the data stream 621, the size of each packet of the encoded data stream 623 is more even. Therefore, transmission resources (e.g., bandwidth) can be used more effectively.

In one embodiment, when the data-encoding pattern does not have an identification code of a certain data stream, it means that the data-encoding device performs a discarding operation on the data stream. Therefore, the encoded data stream output by the data-encoding device keeps no information about this data stream.

It should be understood that the data-encoding patterns 602, 612, and 622 depicted in FIG. 6A-6C are only examples and not limitations. This disclosure does not limit the specific design of the data-encoding pattern, such as dimensions and sizes.

Various embodiments of the system and method provided by the present disclosure can be applied to various scenarios that require data transmission, such as but not limited to various communication networks or data storage. By rearranging the order of transmission data between different streams, transmission resources can be better allocated and utilized. This improves the efficiency and reliability of data transmission. Furthermore, compared with rule-based scheduling policies, the system and method provided in this disclosure can flexibly rearrange the transmission data between different streams based on current transmission resources (e.g., QoS information), characteristics of the data streams (e.g., transmission information) and scheduling policies. This optimizes the underlying scheduling policy, and thus improves the efficiency and reliability of data transmission

The data rearrangement device and method provided by the present disclosure can be applied in various scenarios that require data transmission, such as but not limited to various communication networks or data storage.

The above paragraphs are described in various ways. Obviously, the teachings of this article can be implemented in a variety of ways, and any specific architecture or functionality disclosed in the examples is only a representative situation. Based on the teachings of this article, it should be understood in the art that each aspect disclosed in this article can be implemented independently, or two or more aspects can be combined and implemented.

Although the present disclosure has been described using embodiments as above, they are not intended to limit the present disclosure. A person skilled in the art may make some modifications without departing from the spirit and scope of the present disclosure. Therefore, the protection scope of the invention shall be determined by the appended patent application scope.

What is claimed is:

1. A data rearrangement system, comprising:
a data-decoding device; and
a data-encoding device, configured to:
receive one or more data streams;
generate a data-encoding pattern through a neural network model based on quality of service (QoS) information, a scheduling policy and transmission information of the data streams;
generate an encoded data stream through an encoder by encoding the data streams according to the data-encoding pattern; and
transmit the data-encoding pattern and the encoded data stream to the data-decoding device;
wherein the data-decoding device restores the encoded data stream to the data streams according to the data-encoding pattern.

2. The data rearrangement system as claimed in claim 1, wherein the data-decoding pattern is a binary array indicating a data-arrangement order.

3. The data rearrangement system as claimed in claim 1, wherein the QoS information comprises bandwidth and/or latency between the data-encoding device and the data-decoding device.

4. The data rearrangement system as claimed in claim 1, wherein the transmission information of the data streams comprises data size and/or data type.

5. The data rearrangement system as claimed in claim 1, wherein the data-encoding device is configured to:
detect a variation level of current QoS information, current scheduling policy and current transmission information of one or more current data streams relative to the QoS information, the scheduling policy and the transmission information of the data streams;
compare the variation level and a threshold; and
in response to the variation level that is not less than the threshold, update the data-encoding pattern based on the current QoS information, the current scheduling policy and the current transmission information of the current data streams.

6. The data rearrangement system as claimed in claim 1, wherein the data-encoding device performs data aggregation on the data streams to encode the data streams.

7. The data rearrangement system as claimed in claim 6, wherein the data-encoding device further performs a padding operation, a pruning operation, a balancing operation and/or a discarding operation on the data streams to encode the data streams.

8. A data rearrangement method, executed by a computer system, wherein the computer system comprises a data-encoding device and a data-decoding device, wherein the data rearrangement method comprises:
using the data-encoding device to receive one or more data streams;
using the data-encoding device to generate a data-encoding pattern through a neural network model based on quality of service (QoS) information, a scheduling policy and transmission information of the data streams;
using the data-encoding device to generate an encoded data stream through an encoder encoding the data streams according to the data-encoding pattern;
using the data-encoding device to transmit the data-encoding pattern and the encoded data stream to the data-decoding device; and
using the data-decoding device to restore the encoded data stream to the data streams according to the data-encoding pattern.

9. The data rearrangement method as claimed in claim 8, further comprising:
using the data-encoding device to detect a variation level of current QoS information, current scheduling policy and current transmission information of one or more current data streams relative to the QoS information, the scheduling policy and the transmission information of the data streams;
using the data-encoding device to compare the variation level and a threshold; and
using the data-encoding device to update the data-encoding pattern based on the current QoS information, the current scheduling policy and the current transmission information of the current data streams, in response to the variation level that is not less than the threshold.

10. The data rearrangement method as claimed in claim 8, further comprising:
using the data-encoding device to encode the data streams through data aggregation.
